(19) United States
(12) Patent Application Publication
(10) Pub. No.: US 2015/0034270 A1
(43) Pub. Date: Feb. 5, 2015

(54) AIR CONDITIONING SYSTEM OF DATA CENTER USING HEAT PIPE AND METHOD FOR CONTROLLING THEREOF

(71) Applicant: THERMO-TECH, Seongnam-si (KR)

(72) Inventor: Jong Pil KIM, Guri-si (KR)

(73) Assignee: THERMO-TECH, Seongnam-si (KR)

(21) Appl. No.: 14/230,261

(22) Filed: Mar. 31, 2014

(30) Foreign Application Priority Data
Apr. 26, 2013 (KR) 10-2013-0046445

(51) Int. Cl. H05K 7/20; F28F 27/00

(52) U.S. Cl. CPC H05K 7/20836; F28F 27/00; H05K 7/208
USPC 165/11.1

(57) ABSTRACT

An air conditioning system of data center using heat pipe includes a cooling room that allows air within the data center to be drawn in by a first fan and circulated and fed back to the data center; a heat radiation room located separately from the cooling room; a heat pipe installed such that evaporator and condenser are located in the cooling room and heat radiation room, respectively; a sprayer installed in the heat radiation room and provided with a plurality of spray nozzles for spraying cooling fluid to the condenser; a cooling unit installed in the cooling room and cooling the air that passed the evaporator through heat exchange; dry bulb temperature measurement unit and wet bulb temperature measurement unit; and a control unit that receives the detection signal from the dry and wet bulb temperature measurement units and controls the sprayer and the cooling unit.

### FIELD OF THE INVENTION

The present invention relates to air conditioning system of data center using heat pipe and method for controlling thereof and more particularly, air conditioning system of data center that uses heat pipe and its controlling method with the objective of maintaining the operating environment of information technology related equipment in optimal condition and to block the outside air from flowing into the data center in server room and other areas.

### BACKGROUND ART

Recently, concerns regarding massive blackout had been increasing due to unprecedented electricity shortage caused by intense heat waves in the summer that went over 37 degree Celsius and storms with heavy rain and record breaking cold wave in the winter. Despite these concerns, there is no immediate solution to electricity shortage and all that can be done are managing the demand for electricity and electricity savings campaign.

On the other hand, demand for various data centers had been rapidly increasing as information technology business had been on the rise along with performance and processing ability of information technology equipment. This kind of data center can be described as industrial building that prioritizes maintaining the information technology equipment in optimal condition rather than a place that people live in. Previously, focus had been more on environment control than saving the energy in order to provide stable condition and protection for the equipment. Plans regarding energy savings had not been considered as financial loss that results from error and malfunction of the information technology equipment are bigger than the energy consumption cost.

However, securing continuous growth through information technology is an important mission for the companies in accordance with the global trend and as enormous amount of servers are being operated along with highly integrated data processing due to recent expansion of cloud computing market which causes rapid rise in energy consumption of data center that consumes 40 times more than regular buildings. Consequently, it is now essential for pre-existing Internet Data Centers to become environment friendly and energy saving Green Internet Data Center.

Prior art regarding air conditioning of green Internet Data Center is provided in Korea Public Patent No. 10-2011-0129514 with the title ‘Air conditioning system of Internet Data Center for green computing environment’ regarding heating ventilation and cooling system for green computing environment of Internet Data Center which consists of air conditioner for the cooling and duct for ventilation to efficiently discharge the heat generated from the rack in which the server and network device are mounted to the outside and ventilation opening connected with this and the heat generated from the network device, providing air conditioner control apparatus the information the air conditioner control apparatus controlling the operation of the air-conditioner for the cooling and ventilation and air-conditioner that keeps room temperature of the Internet Data Center, and temperatures are detected for indoor and outdoor which refers to over ground and basement floor.

However, prior art regarding air conditioning system of Internet Data Center is problematic in the sense that energy saving methods were not taken into account.

Further, another example provided regarding cooling method for Internet Data Center of prior art that makes use of common cooling cycle where electricity is provided to the compressor to compress the refrigerant and heat is discharged from the condenser through compressed refrigerant and absorbed by the evaporator. Air cooling thermo hygrostat or water cooling method that cools the interior by installing refrigerating machine to the exterior and providing cooled cold water to the thermo hygrostat is used in order to cool the discharged air from inner part of Internet Data Center with temperature of 35 degree Celsius. This type of cooling methods can be problematic as it does not contribute to energy saving effort as they need to be run for 24 hours and every day for the whole year and as compressor that uses power the most in thermo hygrostat consumes large amounts of power.

Recently, outside air cooling system that directly provides cold air from the outside during in the winter into the Internet Data Center is being used.

However, this type of method is also problematic as automated system that automatically detects the concentration of fine dust in the outside air will be needed and that this method could hurt the stability of the server as noise and humidity of the outside air directly affects Internet Data Center. Further, usage of electricity may increase in order to maintain the right temperature and humidity and that this may cause dehumidification process overload in processing the humidity of outside air.

### SUMMARY OF THE INVENTION

Accordingly, present invention has been made in view of the above mentioned problems occurring in the prior art, and it is an object of the present invention to provide actualization of environment friendly and energy saving data center in the true sense as it maintains information technology related equipment in optimal condition through the use of natural energy which blocks pollutants from outer parts and the outside air from entering the data center in server room and other areas directly and to prevent the loss from inflow of humidity as well as providing detailed system management.

Further objects and advantages of the invention will become apparent from consideration of the drawings and the description.

In order to achieve the above-mentioned object, according to an aspect of the present invention, an air conditioning system of data center using heat pipe is provided which comprises: a cooling room that allows air within the data center to be drawn in by a first fan and circulated and fed back to the data center; a heat radiation room located separately from the cooling room, which room allows outside air to be drawn into the inside through a second fan and then discharged to the outside; a heat pipe installed such that evaporator and condenser are located in the cooling room and heat radiation room, respectively, wherein working fluid repeats phase changes of evaporation and condensation each in the evaporator and condenser, hence, the air passing through the cooling room is cooled by means of heat exchange with the evaporator and the air passing through the heat radiation room has heat exchange with the condenser; a sprayer installed in the heat radiation room and provided with a plurality of spray nozzles for spraying cooling fluid to the condenser; a cooling unit installed in the cooling room and cooling the air that passed the evaporator through heat exchange; dry bulb temperature measurement unit and wet bulb temperature measurement unit that each measures dry and wet bulb temperatures of outside air and output the temperatures as detection signal; and a control unit that receives the detection signal from the dry bulb temperature measurement unit and the wet bulb temperature measurement unit and control the sprayer and the cooling unit,

The cooling room and the heat radiation room may be arranged vertically and a plurality of the heat pipes may be installed vertically in the cooling room and the heat radiation room and connected by heat radiation fins.

The cooling room and the heat radiation room may be arranged horizontally and the heat pipe may be installed horizontally in the cooling room and the heat radiation room.

The control unit may control blowing power of the first and second fans depending on wet bulb temperature and dry bulb temperature that had been each measured by the wet bulb temperature measurement unit and dry bulb temperature measurement unit and controls the sprayer to spray the condenser with the cooling fluid in order to cool the condenser when the dry bulb temperature measured by the dry bulb temperature measurement unit exceeds a first set temperature and the wet bulb temperature measured by the wet bulb temperature measurement unit is less than a second set temperature, and controls the cooling unit to cool, together with the evaporator, air passing through the cooling room when the wet bulb temperature measured by the wet bulb temperature measurement unit exceeds the second set temperature.

According to another aspect of the present invention, a method for controlling air conditioning system of data center using heat pipe is provided, which method comprises: a step of cooling air passing through the cooling room by means of heat exchange with the evaporator and causing air passing through the heat radiation room to have heat exchange with the condenser by activating the heat pipe and the first and second fans; a step of causing the sprayer to spray the condenser with the cooling fluid in order to cool the condenser when dry bulb temperature of the outside air exceeds first set temperature and wet bulb temperature of the outside air is less than second set temperature; and a step of causing the cooling unit together with the evaporator to cool the air passing through the cooling room when the wet bulb temperature of the outside air exceeds the second set temperature.

The method may further comprise a step of cooling the data center by means of indirect cooling of the outside air by activating the first and second fans and heat pipes; and a step of controlling blowing power of the first and second fans depending on wet bulb temperature of the outside air and dry bulb temperature of the outside air.

According to the present invention that pertains to air conditioning system of data center using heat pipe and method for controlling thereof, present invention enables the actualization of environment friendly and energy saving data center in the true sense as it maintains information technology related equipment in optimal condition through the use of natural energy which blocks pollutants from outer parts and the outside air from entering the data center in server room and other areas directly and to prevent the loss from inflow of humidity as well as providing detailed system management.

### BRIEF DESCRIPTION OF THE DRAWINGS

FIG. 1 is an elevation view illustrating air conditioning system of data center using heat pipe according to the first embodiment of the present invention.

FIG. 2 is an elevation view illustrating air conditioning system of data center using heat pipe installed according to the first embodiment of the present invention.

FIG. 3 is a plan view illustrating air conditioning system of data center using heat pipe installed according to the first embodiment of the present invention.

FIG. 4 is a block diagram illustrating air conditioning system of data center using heat pipe according to the first embodiment of the present invention.

FIG. 5 is a perspective view illustrating an example of installed structure of air conditioning system for data center using heat pipe according to the first embodiment of the present invention.

FIG. 6 is a plan view illustrating another example of installed structure of air conditioning system for data center using heat pipe according to the first embodiment of the present invention.

FIG. 7 is a perspective view illustrating yet another example of installed structure of air conditioning system for data center using heat pipe according to the first embodiment of the present invention.

FIG. 8 is a perspective view illustrating yet another example of installed structure of air conditioning system for data center using heat pipe according to the first embodiment of the present invention.

FIG. 9 is an elevation view illustrating air conditioning system of data center using heat pipe installed according to the second embodiment of the present invention.

FIG. 10 is a flow chart illustrating the control method of air conditioning system of data center using heat pipe according to the present invention.

### DETAILED DESCRIPTION OF THE EMBODIMENTS

Embodiments of the disclosure are discussed in detail with the drawings as there may be various embodiments and changes that may be applied. While the present invention has been described with reference to the particular illustrative embodiments, it is not to be restricted by the embodiments but only by the appended claims and are therefore not to be considered limiting of its scope, for the invention may admit to other equally effective embodiments.

As below, embodiments according to the invention are discussed in detail in reference to the drawings and labels will be the same even when the drawing changes when it concerns the same embodiments to exclude repeated explanations.

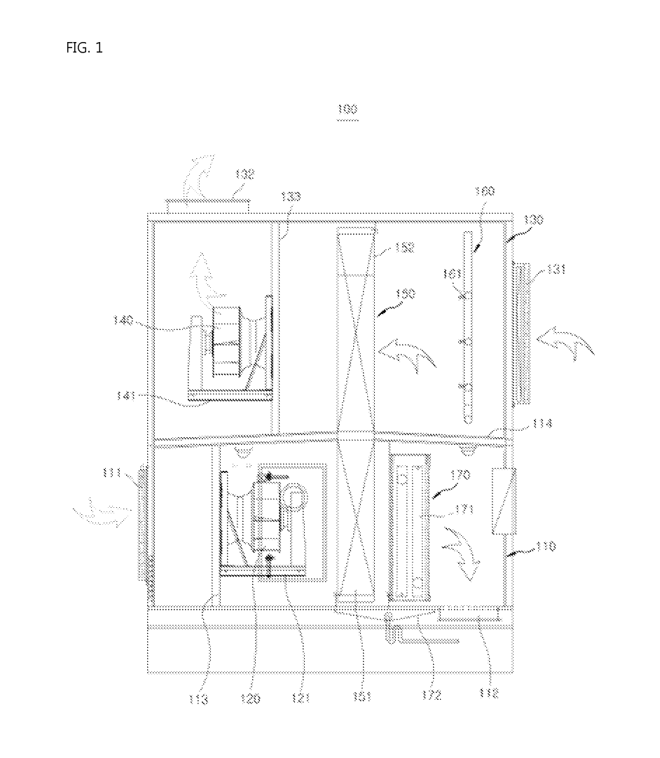

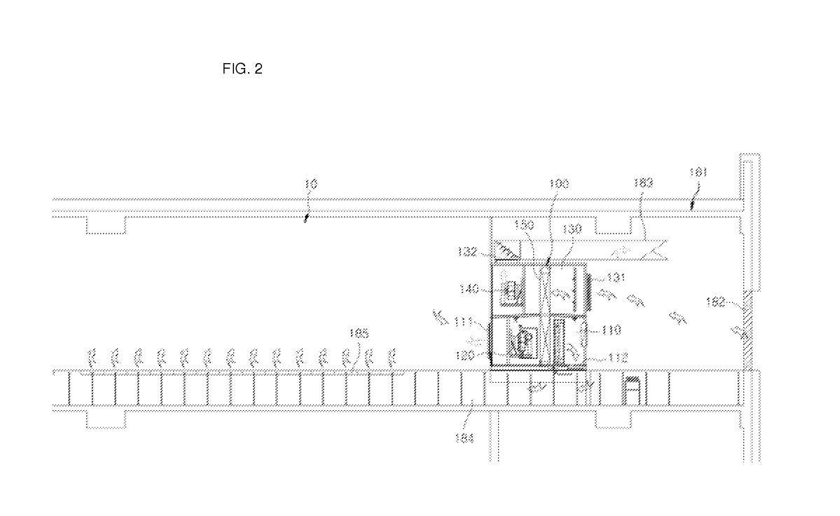

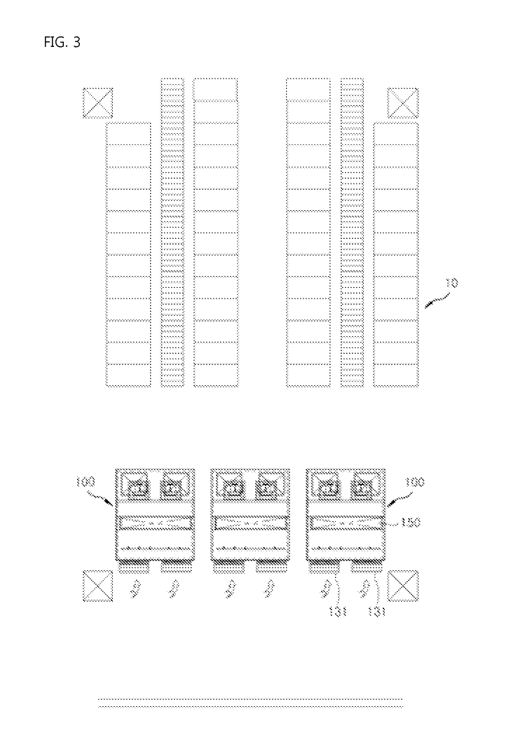

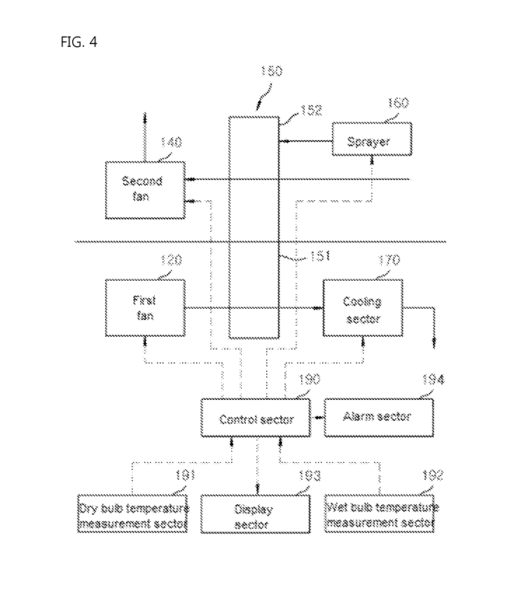

FIG. 1 is an elevation view illustrating air conditioning system of data center using heat pipe according to the first embodiment of the present invention and FIG. 2 and FIG. 3 is an elevation view illustrating air conditioning system of data center using heat pipe installed according to the first embodiment of the present invention and FIG. 4 is a block diagram illustrating air conditioning system of data center using heat pipe according to the first embodiment of the present invention.

As illustrated in FIG. 1 to FIG. 4, air conditioning system 100 of data center using heat pipe according to a first embodiment of the present invention comprises cooling room 110, heat radiation room 130, heat pipe 150, sprayer 160, cooling unit 170, dry bulb temperature measurement unit 191, wet bulb temperature measurement unit 192 and control unit 190. On the other hand, cooling room 110, heat radiation room 130, heat pipe 150, sprayer 160 and cooling unit 170 may be singularly installed for each data center 10 or by multiple numbers such as three of them as shown in the present embodiment and may change its number according to size of the data center, and may be installed in the air conditioning room 181 placed in one side of the data center 10.

The cooling room 110 allows air within the data center 10 to be drawn in by first fan 120 and circulated and fed back to the data center 10, and for this process, inlet 111 for inflow of the air within the data center and feeding inlet 112 for providing the air to the data center 10 are provided. The number of inlets 111 and feeding inlets 112 may be corresponding to the number of first fans 120.

Further, the data center 10 could also include not only the Internet Data Center (IDC) that accommodates servers for internet communication and information technology related equipment but also data processing room that holds information technology related equipment for data processing and storage.

The first fan 120 provides blowing power for circulation of air of the data center 10 through the inlet 111 and feeding inlet 112 via the cooling room 110 into the data center 10. Further, the first fan 120 may be fixed to the partition 113 with the bracket 121, which partition is vertically installed in the cooling room 110 while facing a evaporator 151 of the heat pipe 150 which will be described as below and air may be blown through an opening (not illustrated) formed in the partition 113.

The heat radiation room 130 is located separately from the cooling room 110 and allows outside air to be drawn into the inside by means of second fan 140 and then discharged to the outside, and for this purpose, provided are an intake port 131 for drawing the outside air into the inside and an exhaust port 132 for discharging the drawn air to the outside. The intake port 131 and exhaust pipe 132 may be provided in the number corresponding to the number of second fans 140. Further, the outside air may be drawn into the intake port 131 through the suction part 182 placed in the air conditioning room 181 in the form of an opening, and the exhaust port 132 can discharge air in the heat radiation room 130 exhaust duct 183 by being connected to the exhaust duct 183.

Second fan 140 provides blowing power in order for the outside air to pass through the heat radiation room 130 by means of the intake port 131 and exhaust port 132. Further, the second fan 140 may be fixed to a partition 133 with a bracket 141, which partition is vertically installed in the heat radiation room 130 while facing a condenser 152 of the heat pipe 150 which will be described as below and air may be blown through an opening (not illustrated) formed in the partition 133.

The first and second fans 120, 140 may be electronically commutated fan for example, and is able to maintain optimal operational condition through electric control, and as the fans use high efficient motor with less electricity consumption by 30 to 50 percent compared to normal alternating-current motors, the fans can be suitable for a fan for data center 10 with high electricity consumption. Further, the first and second fans 120, 140 can make use of motor of which the number of rotation can be easily adjusted depending on the temperature of the outside air and can be installed singularly or plural in each cooling room 110 and heat radiation room 130.

The heat pipe 150 is installed such that the evaporator 151 and condenser 152 are located in the cooling room 110 and heat radiation room 130, respectively. Working fluid repeats phase changes of evaporation and condensation each in the evaporator 151 and condenser 152, hence, the air passing through the cooling room 110 is cooled by means of heat exchange with the evaporator 151 and the air passing through the heat radiation room 130 has heat exchange with the condenser 152.

By repeating the phase change of evaporation and condensation through working fluid which is a volatile liquid placed within the container sealed with decompression or vacuum, the heat pipe 150 transfers heat thousand times or more faster than heat transfer methods such as natural convection or conduction and can be comprised of wick with inner porous structure such as felt, foam, fiber and metal net etc. and vapor space. Evaporator 151 increases the temperature of working fluid and accelerates the evaporation through heat absorption, and steam of the working fluid resulting from evaporation moves to the condenser 152 through the vapor space and goes through the condensation process while discharging the condensation latent heat, and the working fluid condensed in the condenser 152 moves to the evaporator 151 by gravity or by capillary action. Further, heat pipe 150 can use, as heat source, heat of the air provided through the inlet 111 from the data center 10 or use a separate heating source.

The sprayer 160 can be installed to help cool the condenser 152 of the heat pipe 150 within the heat radiation room 130. Sprayer 160 can have multiple spray nozzles 161 to spray the condenser 152 with coolant such as water and comprise pipe installed opposite to the condenser 152, and a plurality of spray nozzles 161 can be arranged in vertical direction or horizontal direction or in both directions. The water provided by pumping power of the outer pump is sprayed to the condenser 152 through the spray nozzles 161 to cool the condenser 152.

The cooling unit 170 can be installed in the back side of the condenser 151 of the heat pipe 150 in the cooling room 110, and for cooling the air that passed through the evaporator 151, may have cooling coil 171 in which cooled water cooled through a cooling device (for example, device utilizing cooling cycle) is circulated by means of pumping power of a circulation pump. Further, collecting part 172 may be installed at the lower part of the cooling coil 171 in order to collect and discharge the condensed water formed by the cooling of air.

Further, main supply route 184 may be installed on the lower part of the floor which is lower section of the data center 10. Main supply route 184 is connected to feeding inlet 112 of the cooling room 110 and forms a passage for distributing and discharging the cooled air cooled through heat exchange with the cooling coil 171 through a plurality of outlets 185 provided in the bottom of the data center 10.

Further, the cooling room 110 and heat radiation room 130 is separated by partition 114 and may be arranged vertically. Then, the heat pipe 150 may be installed vertically such that the evaporator 151 and condenser 152 are positioned within the cooling room 110 and heat radiation room 130, respectively.

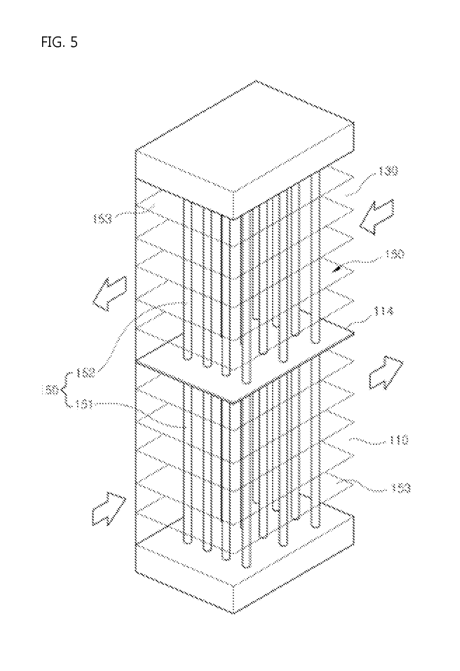

In reference to FIG. 5, heat pipe 150 is installed vertically in the cooling room 110 and heat radiation room 130 and can be installed side by side to be connected by heat radiation fin 153 which is installed horizontally and arranged on upper and lower direction in multiple numbers where it helps increase the heat exchange efficiency with the air passing through the cooling room 110 through first fan 120. Heat radiation fin 153 can have multiple penetration hole (not illustrated) in order for heat pipes 150 to penetrate.

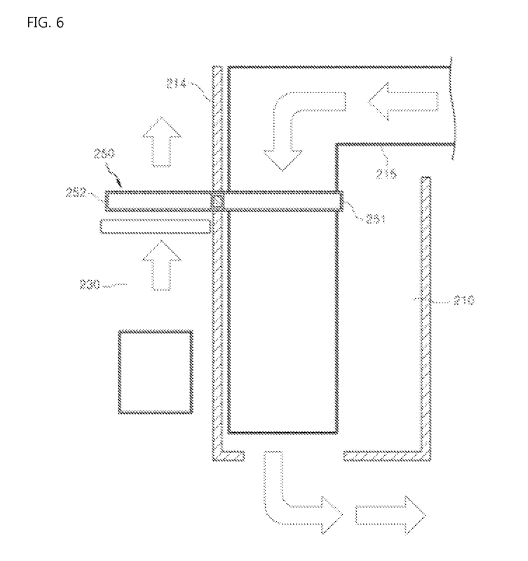

In reference to FIG. 6, cooling room 210 and heat radiation room 230 is separated by partition 214 and arranged horizontally. Then heat pipe 250 can be installed horizontally in the cooling room 210 and heat radiation room 230 in order for evaporator 251 would be installed in the cooling room 210 and condenser to be installed in the heat radiation room 230. Then, evaporator 251 is installed in the duct 215 in the cooling room 210.

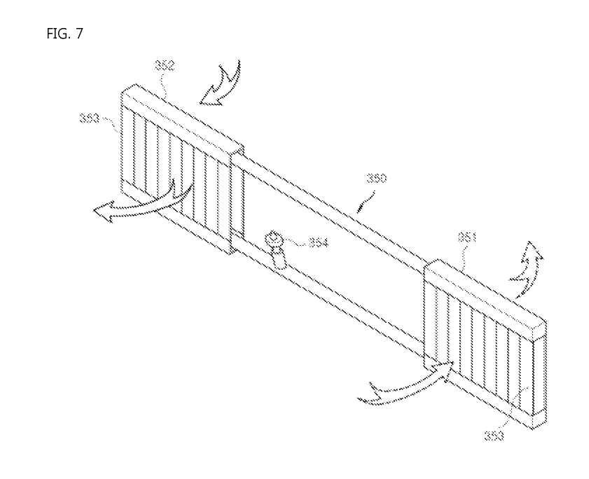

In reference to FIG. 7, heat pipe 350 is installed so that evaporator 351 and condenser 352 will be installed in the cooling room and heat radiation room when cooling room and heat radiation room is separated horizontally where heat pipe can be formed into the shape of a loop through bending in order to circulate the cooling room and heat radiation room and installed in multiple number on the evaporator 351 and condenser 352 and partially connected by heat radiation fin 353. In order to partially connect the heat pipe 350 to evaporator 351 and condenser 352, it may be installed side by side vertically so that the part that face each other in the part that has the shape of ‘ [symbol] ’ in the embodiment where it forms evaporator 351 and condenser 352 in the heat pipe 350. Further, opening and closing part 354 can be provided in the in the heat pipe 350 to insert and discharge the working fluid.

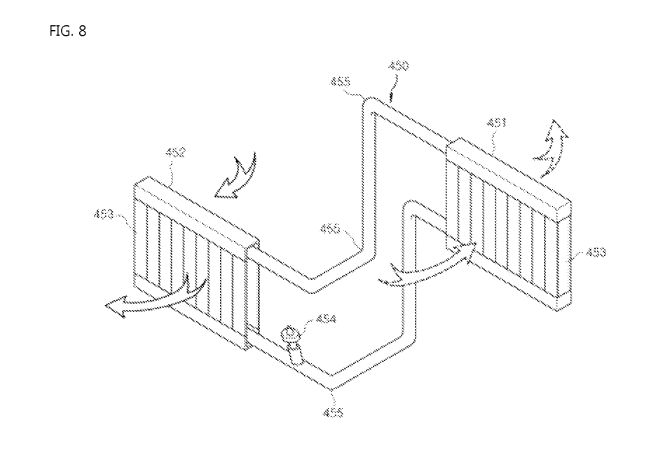

In reference to FIG. 8, heat pipe 450 is installed so that evaporator 451 and condenser 452 will be installed in the cooling room and heat radiation room when cooling room and heat radiation room is separated horizontally and vertically where heat pipe can be formed into the shape of a loop through bending in order to circulate the cooling room and heat radiation room and installed in multiple number on the evaporator 451 and condenser 452 and partially connected by heat radiation fin 453. In order to partially connect the heat pipe 450 to evaporator 451 and condenser 452, it may be installed side by side vertically so that the part that face each other in the part that has the shape of ‘ [symbol] ’ in the embodiment where it forms evaporator 351 and condenser 452 in the heat pipe 450. Further, opening and closing part 454 can be provided in the in the heat pipe 450 to insert and discharge the working fluid. Further, position of the evaporator 451 and condenser 452 can be variously separated by bent section 455 that forms through bending.

In reference to FIG. 4, dry bulb temperature measurement unit 191 can be installed in the various parts that can measure the dry bulb temperature including air conditioning room 181 as seen on FIG. 2 and measure the temperature that thermometer measures by exposing a temperature sensing portion of the thermometer to the air without direct contact with sunlight and output the temperature to the control unit 190 as detection signal.

Wet bulb temperature measurement unit 192 can be installed in the various parts that can measure the wet bulb temperature including air conditioning room 181 as seen on FIG. 2 and send the sensor signal after measuring the wet bulb temperature which refers to temperature that dropped as much as water evaporated from wet bulb wet with water such as distilled water as air is saturated that can be shown in the control unit 190.

Control unit 190 receives the sensor signal from dry bulb temperature measurement unit 191 and wet bulb temperature measurement unit 192 and controls the sprayer 160 and cooling unit 170. Control unit 190 can not only control sprayer 160 and cooling unit 170 and also the actions of first and second fan 120, 140 and heat pipe 150 as well as sprayer 160 that can be controlled by controlling the pump and spraying the coolant. In case of cooling unit 170, it can be controlled by cooling equipment for cooling the cooling water and circulation and the pump.

As an example, control unit 190 activates the sprayer 160 to spray the condenser with the coolant in order to cool the condenser when dry bulb temperature measured by dry bulb temperature measurement unit 191 exceeds first set temperature and when wet bulb temperature measured by wet bulb temperature measurement unit 192 is less than second set temperature and control the cooling unit 170 to cool, together with the evaporator 151, the air passing the cooling room 110 when the wet bulb temperature measured by wet bulb temperature measurement unit 192 exceeds second set temperature. First and second set temperatures can be determined by size and target temperature of the data center 10 and as an example, it can be set as 20 degree Celsius or other temperature as setpoint. Further, first and second temperature can be set by control of the user and control unit 190 can receive the sensor signal that was emitted by control of the user and carry out the control with the sensor signal as the basis.

Further, control unit 190 can control the blowing power of the first and second fan 120, 140 based on the dry bulb heat that was measured by dry bulb heat temperature unit 191 and wet bulb heat that was measured by wet bulb heat temperature unit 192. Speed of the motor rotation of the first and second fan 120, 140 can be controlled so that dry bulb temperature and wet bulb temperature of the outside air would reach the first and second set temperatures where dry bulb temperature and wet bulb temperature of the outside air and status of the operation can be displayed by display unit 193 to the outside. When dry bulb temperature and wet bulb temperature exceeds the first and second set temperatures, it can emit an alarm or turn off the alarm through alarm unit 194.

Detailed control method carried out by control unit 190 will be explained further in the control method of air conditioning system of data center using heat pipe according to the present invention.

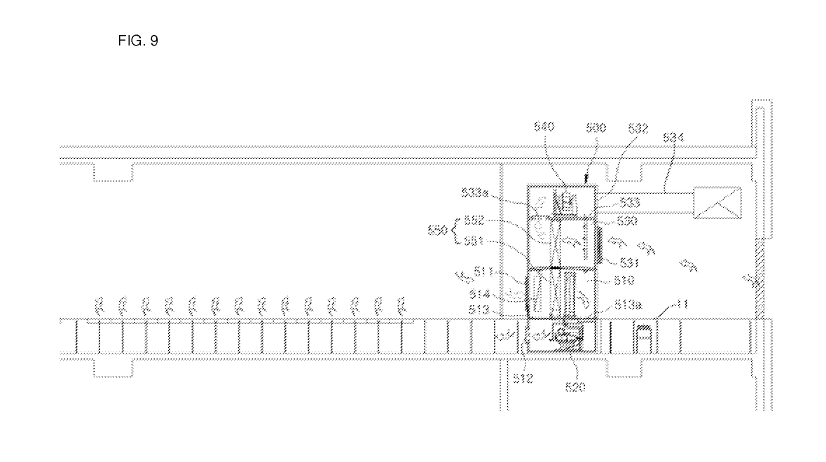

In reference to FIG. 9, air conditioning system of data center using heat pipe 500 comprises of inlet 511, cooling room 510 with feeding inlet 512, first fan 520, intake port 531, heat radiation room 530 with exhaust pipe 532, second fan 540, heat pipe 550, sprayer 160 as illustrated in FIG. 4, cooling unit 170 as illustrated in FIG. 4, dry bulb temperature measurement unit 191 as illustrated in FIG. 4, wet bulb temperature measurement unit 192 as illustrated in FIG. 4 and control unit 190 as illustrated in FIG. 4 in the same manner with first embodiment of air conditioning system of data center using heat pipe 100. First fan 520 can be installed in the lower part of the floor 11 of the data center in order to be placed in the low part of the partition 513 which is in the low part of the evaporator 551 in the cooling room 510. Second fan 540 can be installed in the exhaust duct 534 in order to be placed in the top part of the partition 533 which is the top part of condenser 552 in the heat radiation room. An opening 513a, 533a may be formed so that air may pass through the partition 513, 533.

Further, filter 514 can be installed on the inner part of the cooling room 510 to filter the foreign substances in the air in the embodiment of the invention.

In accordance with air conditioning system of data center using heat pipe of present invention, heat pipe 150 that makes use of working fluid with repeat phase change of evaporation and condensation that provides excellent heat transfer effect to cool the air provided to the data center 10 through circulation. By activating the first fan 120, warm air within the data center 10 with the temperature of 32 to 35 degree Celsius pass through the cooling room 110 and through evaporator 151 of the heat pipe 150 and cold outside air pass through heat radiation room 130 and condenser 152 of the heat pipe when second fan 140 is activated. Through the phase change of the working fluid such as evaporation in the evaporator 151 and condensation of the condenser 152, air that passes the cooling room 110 is cooled through heat exchange with the evaporator 151 and outside air that passes through heat radiation room 130 goes through heat exchange with the condenser 152.

There is no direct contact of outside air with server in the data center 10 with this type of indirect heat exchange, it can block the foreign substances in the outside air from entering the data center 10 and also block the moisture in the outside air from entering the data center 10 to prevent additional loss of energy which enables the detailed management of the data center 10.

In case where height of the data center 10 is limited by structure of the building, evaporator 251 and condenser 252 of the heat pipe 250 can be arranged horizontally as illustrated on FIG. 6 and it is possible to separately install the evaporator 351 and condenser 352 of the heat pipe horizontally as illustrated on FIG. 7 and evaporator 451 and condenser 452 of the heat pipe 450 can be separately installed horizontally as illustrated on FIG. 8.

In case where there is not enough cooling in the data center 10 when temperature of the outside air is not low enough as summer approaches through climate change, coolant such as water is sprayed through spray nozzle 161 of the sprayer 160 to cool the outside air by evaporating the latent heat of 540 kcal/kg. When temperature of the outside air is cooled through evaporating the coolant, air supplied to the data center 10 is also lowered and it is possible to additionally cool the data center 10 through outside air in the summer. As indirect cooling method of the outside air does not increase the humidity of the data center caused by spraying the water, it can be used as an effective method of cooling even in the warm weather.

Further, efficiency of cooling process for data center 10 can be increased by additional cooling related control through sprayer 160 and cooling unit 170 in accordance with dry bulb heat or wet bulb heat.

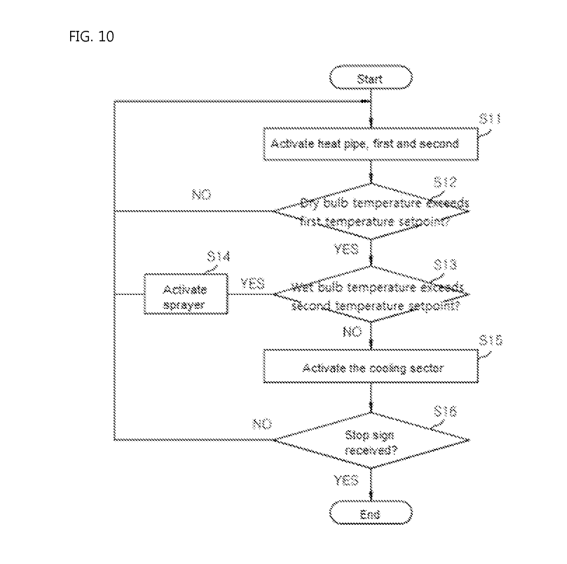

FIG. 10 is a flow chart illustrating the control method of air conditioning system of data center using heat pipe according to the present invention.

In reference to FIG. 10, control method of air conditioning system of data center using heat pipe according to the present invention and the embodiment of the present invention where control unit 190 activates the heat pipe 150 and first and second fans 120, 140 to cool the air that passes the cooling room 110 through heat exchange with the evaporator 151 and cause the air that passes through the heat radiation room 120 to have heat exchange with the condenser 152 (S11).

As heat pipe 150 and first and second fan 120, 140 is activated, control unit 190 activates the sprayer 160 to spray the condenser 152 with the cooling fluid, i.e., water in order to cool the condenser 152 (S14) when dry bulb temperature of outside air measured by dry bulb temperature unit 191 exceeds first set temperature (S12) and when wet bulb temperature of outside air measured by wet bulb temperature measurement unit 192 is less than second set temperature (S13). First and second set temperatures can be determined by size and target temperature of the data center 10 and as an example, it can be set as 20 degree Celsius or other temperature as setpoint. Further, first and second temperature can be set by control of the user and control unit 190 can receive the sensor signal that was emitted by control of the user and carry out the control with the sensor signal as the basis.

Furthermore, the control unit 190 causes the cooling unit 170 together with the evaporator 151 to cool the air passing through the cooling room 110 when the wet bulb temperature of the outside air measured by wet bulb temperature measurement unit 192 exceeds the second set temperature. (S15). Such processes are performed until stop signal of the air conditioning system is received by the control unit 190.

Moreover, control unit 190 cools the data center 10 only through indirect cooling of outside air by activating heat pipe 150 and first and second fan 120, 140 when dry bulb temperature of outside air measured by dry bulb measurement unit 191 is less than first set temperature. Further, control unit 190 can control the blowing power of the first and second fan 120, 140 based on the dry bulb temperature of outside that was measured by dry bulb heat temperature unit 191 and wet bulb temperature of outside air that was measured by wet bulb heat temperature unit 192. Speed of the motor rotation of the first and second fans 120, 140 can be controlled so that dry bulb temperature and wet bulb temperature of the outside air would reach the first and second set temperatures.

Thus, according to control method of air conditioning system of data center using heat pipe of the present invention, energy source needed for cooling the environment friendly data center is outside temperature and humidity and right temperature of the data center 10 can be maintained by changing the amount of heat exchange of the heat pipe 150 by controlling the volume of air according to the temperature of outside air that changes through the season. Further, energy consumption can be minimized through indirect cooling of outside air by heat pipe 150 and first and second fan 120, 140 according to the temperature and humidity condition of the outside air which is the first step, indirect evaporation cooling by the sprayer 160 which is the second step and switching the operation mode to cooling through cooling unit 170 which is the third step.

For instance, when dry bulb temperature of outside air is less than 20 degree Celsius, it can be cooled 100 percent by outside air. And when the dry bulb temperature of outside air is more than 20 degree Celsius and wet bulb temperature is less than 20 degree Celsius, indirect cooling by heat pipe 150 and indirect evaporative cooling that lowers the outside temperature to 20 degree Celsius by evaporative cooling system that makes use of sprayer 160 installed in the outside air suction to cool the data center 10. Further, when the humidity temperature of outside air is more than 20 degree Celsius, data center 10 can be cooled through outside air indirect evaporative cooling of mechanical cooling unit 170 as operated by cooling cycle or outside air indirect cooling by heat pipe 150.

In case of Korea, data center is cooled through 100 percent outside air from step 1 for 6421 hours which is 73.3 percent of the 8760 hours which is the total cooling period of the data center per year. Case where data center is cooled by outside air cooling and indirect evaporative cooling which is the second step is 893 hours which is 10.2 percent and when data center is cooled through mechanical cooling method that uses electricity is 1446 hours which is 16.5 percent when energy efficiency according to the present invention by making use of weather data from Kimpo Airport observatory is calculated. In case of Korea that has distinctive four seasons, 7314 hours of operation hours of thermo hygrostat per year which amounts to 83.5 percent can be operated by environment friendly cooling system and thus saving enormous amount of energy.

It is an object of the present invention to provide actualization of environment friendly and energy saving data center in the true sense as it maintains information technology related equipment in optimal condition through the use of natural energy which blocks pollutants from outer parts and the outside air from entering the data center in server room and other areas directly and to prevent the loss from inflow of humidity as well as providing detailed system management.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention. Therefore, present invention has been described with reference to the particular illustrative embodiments and not to be restricted by the embodiments but only by the appended claims.

### DESCRIPTION OF REFERENCE NUMERALS

110: Cooling room
111: Inlet
112: Feeding inlet
113: Partition
114: Wall
120: First fan
121: Bracket
130: Heat radiation room
131: Intake port
132: Exhaust pipe
141: Bracket
150: Heat pipe
151: Evaporator
152: Condenser
153: Heat radiation fin
160: Sprayer
161: Sprayer nozzle
170: Cooling unit
171: Cooling coil
172: Collecting unit
181: Air conditioning room
182: Suction unit
183: Exhaust duct
184: Main route
185: Outlet
190: Control unit
191: Dry bulb temperature measurement unit
192: Wet bulb temperature measurement unit
193: Display unit
194: Alarm unit
210: Cooling room
215: Duct
230: Heat radiation room
250: Heat pipe
251: Evaporator
252: Condenser
350: Heat pipe
351: Evaporator
352: Condenser
353: Heat radiation fin
354: Opening and closing part
450: Heat pipe
451: Evaporator
452: Condenser
453: Heat radiation fin
454: Opening and closing part
455: Bent section
510: Cooling room
511: Inlet
512: Feeding inlet
513: Partition
513a: Opening
514: Filter
520: First fan
530: Heat radiation room
531: Intake port
532: Exhaust pipe
533: Partition
533a: Opening
534: Exhaust duct
540: Second fan
550: Heat pipe
551: Evaporator
552: Condenser

1. An air conditioning system of data center using heat pipe comprising:
a cooling room that allows air within the data center to be drawn in by a first fan and circulated and fed back to the data center;
a heat radiation room located separately from the cooling room, which room allows outside air to be drawn into the inside through a second fan and then discharged to the outside;
a heat pipe installed such that evaporator and condenser are located in the cooling room and heat radiation room, respectively, wherein working fluid repeats phase changes of evaporation and condensation each in the evaporator and condenser, hence, the air passing through the cooling room is cooled by means of heat exchange with the evaporator and the air passing through the heat radiation room has heat exchange with the condenser;
a sprayer installed in the heat radiation room and provided with a plurality of spray nozzles for spraying cooling fluid to the condenser;
a cooling unit installed in the cooling room and cooling the air that passed the evaporator through heat exchange;
dry bulb temperature measurement unit and wet bulb temperature measurement unit that each measures dry and wet bulb temperatures of outside air and output the temperatures as detection signal; and
a control unit that receives the detection signal from the dry bulb temperature measurement unit and the wet bulb temperature measurement unit and control the sprayer and the cooling unit,
wherein the control unit controls blowing power of the first and second fans depending on wet bulb temperature and dry bulb temperature that had been each measured by the wet bulb temperature measurement unit and dry bulb temperature measurement unit and controls the sprayer to spray the condenser with the cooling fluid in order to cool the condenser when the dry bulb temperature measured by the dry bulb temperature measurement unit exceeds a first set temperature and the wet bulb temperature measured by the wet bulb temperature measurement unit is less than a second set temperature, and controls the cooling unit to cool, together with the evaporator, air passing through the cooling room when the wet bulb temperature measured by the wet bulb temperature measurement unit exceeds the second set temperature.

2. The air conditioning system of data center using heat pipe of claim 1 wherein the cooling room and the heat radiation room are arranged vertically and a plurality of the heat pipes are installed vertically in the cooling room and the heat radiation room and connected by heat radiation fins.

3. The air conditioning system of data center using heat pipe of claim 1 wherein the cooling room and the heat radiation room are arranged horizontally and the heat pipe is installed horizontally in the cooling room and the heat radiation room.

4. A method for controlling air conditioning system of data center using heat pipe of claim 1 wherein the method comprises:
a step of cooling air passing through the cooling room by means of heat exchange with the evaporator and causing air passing through the heat radiation room to have heat exchange with the condenser by activating the heat pipe and the first and second fans;
a step of causing the sprayer to spray the condenser with the cooling fluid in order to cool the condenser when dry bulb temperature of the outside air exceeds first set temperature and wet bulb temperature of the outside air is less than second set temperature; and
a step of causing the cooling unit together with the evaporator to cool the air passing through the cooling room when the wet bulb temperature of the outside air exceeds the second set temperature.

5. The method for controlling air conditioning system for data center using heat pipe of claim 4 wherein the method further comprises:
a step of cooling the data center by means of indirect cooling of the outside air by activating the first and second fans and heat pipes; and
a step of controlling blowing power of the first and second fans depending on wet bulb temperature of the outside air and dry bulb temperature of the outside air.
